(19) United States
(12) Patent Application Publication
(10) Pub. No.: US 2025/0386619 A1
(43) Pub. Date: Dec. 18, 2025

(54) LIGHT-DIRECTING STRUCTURES IN LIGHT-EMITTING DIODE DEVICES AND RELATED METHODS

(71) Applicant: CreeLED, Inc., Durham, NC (US)

(72) Inventors: Steven Wuester, Wake Forest, NC (US); Nikolas Hall, Durham, NC (US); Michael Check, Holly Springs, NC (US)

(21) Appl. No.: 18/745,203

(22) Filed: Jun. 17, 2024

(51) Int. Cl. H01L 33/44; H01L 33/00

(52) U.S. Cl. CPC H10H 20/84; H10H 20/01; H10H 20/034

(57) ABSTRACT

Solid-state lighting devices including light-emitting diodes (LEDs) and more particularly light-directing structures in LED devices and related methods are disclosed. Exemplary light-directing structures include light-extraction films having one or more light-extraction elements with internal cavities for shaping emissions. Light-extraction elements and corresponding internal cavities are shaped to direct light emissions off center to provide LED devices with wider angle emissions. Internal cavities may be at least partially embedded within light-extraction films. Internal cavities may be bounded by angled inner sidewalls. Angled shapes of inner sidewalls and/or further angled shapes of outer sidewalls of light-extraction elements may effectively promote light to exit the LED chip at desired emission angles. Exemplary LED devices include LED chips and LED packages.

### FIELD OF THE DISCLOSURE

The present disclosure relates to solid-state lighting devices including light-emitting diodes (LEDs) and more particularly to light-directing structures in LED devices and related methods.

### BACKGROUND

Light-emitting diodes (LEDs) are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions.

LEDs have been widely adopted in various illumination contexts, for backlighting of liquid crystal display (LCD) systems (e.g., as a substitute for cold cathode fluorescent lamps) and for direct-view LED displays. Applications utilizing LED arrays include vehicular headlamps, roadway illumination, light fixtures, and various indoor, outdoor, and specialty contexts. Desirable characteristics of LED devices include high luminous efficacy in intended emission directions and long lifetime.

Typically, it is desirable to operate LEDs at the highest light emission efficiency possible, which can be measured by the emission intensity in relation to the output power. A practical goal to enhance emission efficiency is to maximize extraction of light in an intended emission pattern. Light extraction and external quantum efficiency of an LED can be limited by a number of factors, including internal reflection. As LED applications continue to advance, challenges exist in producing high quality light with desired emission patterns while also providing high light emission efficiency.

The art continues to seek improved LED devices with enhanced emission characteristics while overcoming limitations associated with conventional devices and production methods.

### SUMMARY

The present disclosure relates to solid-state lighting devices including light-emitting diodes (LEDs) and more particularly to light-directing structures in LED devices and related methods. Exemplary light-directing structures include light-extraction films having one or more light-extraction elements with internal cavities for shaping emissions. Light-extraction elements and corresponding internal cavities are shaped to direct light emissions off center to provide LED devices with wider angle emissions. Internal cavities may be at least partially embedded within light-extraction films. Internal cavities may be bounded by angled inner sidewalls. Angled shapes of the inner sidewalls and/or further angled shapes of outer sidewalls of light-extraction elements may effectively promote light to exit the LED chip at desired emission angles. Exemplary LED devices include LED chips and LED packages.

In one aspect, an LED chip comprises: an active LED structure comprising an n-type layer, a p-type layer, and an active layer between the n-type layer and the p-type layer; and a light-extraction film on the active LED structure, the light extraction film comprising a light-extraction element that includes an internal cavity bounded by inner sidewalls of the light-extraction film. The LED chip may further comprise a substrate between the active LED structure and the light-extraction film. In certain embodiments, a base of the internal cavity is positioned closer to the active LED structure than a top of the internal cavity, and the base of the internal cavity is wider than the top of the internal cavity. In certain embodiments, the top of the internal cavity is open at a surface of the light-extraction film. In certain embodiments, the internal cavity forms a shape of a cone within the light-extraction element. In certain embodiments, the light-extraction element forms a shape of a polygonal pyramid structure. In certain embodiments, the light-extraction element is one of a plurality of light-extraction elements, and each light-extraction element of the plurality of light-extraction elements includes a separate internal cavity bounded by angled sidewalls of the light-extraction film. In certain embodiments, the inner sidewalls of the light-extraction element are formed at a first angle in a range from 15 to 45 degrees from a direction perpendicular to a longitudinal plane of the active LED structure. In certain embodiments, the light-extraction element is bounded by outer sidewalls of the light-extraction element, and the outer sidewalls are formed at a second angle in a range from 30 to 60 degrees from the direction perpendicular to the longitudinal plane of the active LED structure. In certain embodiments, a ratio of a height of the light-extraction element to a width of the light-extraction element is in a range from one-to-one up to three-to-one.

In another aspect, a method comprises: providing an active light-emitting diode (LED) structure comprising an n-type layer, a p-type layer, and an active layer between the n-type layer and the p-type layer; forming a light extraction film on the active LED structure; and forming a light-extraction element in the light extraction film, the light-extraction element forming an internal cavity bounded by inner sidewalls of the light-extraction film. In certain embodiments, forming the light-extraction element comprises: depositing a first portion of the light-extraction film; forming an island of material on the first portion of the light extraction film; depositing a remaining portion of the light-extraction film over the island of material; and removing the island of material to form the internal cavity of the light-extraction element. The method may further comprise etching the island of material to form a first shape before depositing the remaining portion of the light-extraction film, wherein the first shape corresponds with a shape of the internal cavity. The method may further comprise exposing a top surface of the island of material at a top surface of the light-extraction film before removing the island of material. In certain embodiments, a base of the internal cavity is positioned closer to the active LED structure than a top of the internal cavity, and the base of the internal cavity is wider than the top of the internal cavity.

In another aspect, an LED package comprises: an LED chip; and a light-extraction film on the LED chip, the light extraction film comprising a plurality of light-extraction elements, each light-extraction element of the plurality of light-extraction elements forming an internal cavity bounded by inner sidewalls of the light-extraction film. The LED package may further comprise a cover structure on the LED chip, the cover structure comprising a support element, wherein the light-extraction film is on the support element. The LED package may further comprise a support structure on which the LED chip is mounted, the support structure comprising a submount or a lead frame structure. In certain embodiments, a base of the internal cavity is positioned closer to the LED chip than a top of the internal cavity, and the base of the internal cavity is wider than the top of the internal cavity. In certain embodiments, a ratio of a height of each light-extraction element of the plurality of light extraction elements to a width of each light-extraction element of the plurality of light extraction elements is in a range from one-to-one up to three-to-one. In certain embodiments, each light-extraction element is bounded by outer sidewalls, and wherein the inner sidewalls and the outer sidewalls are formed at angles offset from a direction perpendicular to a longitudinal plane of an active LED structure of the LED chip.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### Brief Description of the Drawing Figures

The accompanying drawing figures incorporated in and forming a part of this specification illustrate several aspects of the disclosure, and together with the description serve to explain the principles of the disclosure.

FIG. 1 is a cross-sectional view of an exemplary LED chip according to principles of the present disclosure.

FIG. 2A is a generalized cross-sectional view of an LED chip that is similar to the LED chip of FIG. 1 for embodiments that include a light-extraction film with light-extraction elements.

FIG. 2B is an expanded cross-sectional view of one of the light-extraction elements of FIG. 2A.

FIG. 3A is a general cross-sectional view of an LED chip where a top surface of the LED chip is generally planar.

FIG. 3B is plot of a far field emission pattern of the LED chip of FIG. 3A.

FIG. 4A is a general cross-sectional view of an LED chip where a top surface of the LED chip is formed with a nonplanar shape.

FIG. 4B is plot of a far field emission pattern of the LED chip of FIG. 4A.

FIG. 5A is a general cross-sectional view of a portion of the LED chip of FIG. 2A according to principles of the present disclosure.

FIG. 5B is plot of a far field emission pattern of the LED chip of FIG. 5A.

FIG. 6A is a cross-sectional view of the LED chip of FIG. 2A after a fabrication step for the forming a portion of the light-extraction film.

FIG. 6B is a cross-sectional view of the LED chip of FIG. 6A after a subsequent fabrication step where a number of islands or dots are formed on the light-extraction film.

FIG. 6C is a cross-sectional view of the LED chip of FIG. 6B after a subsequent fabrication step where the first photoresist of FIG. 6B is removed and the islands are etched to form a shape.

FIG. 6D is a cross-sectional view of the LED chip of FIG. 6C after a subsequent fabrication step where a remaining portion of the light-extraction film is deposited on the islands and previously formed portion of the light-extraction film.

FIG. 6E is a cross-sectional view of the LED chip of FIG. 6D after a subsequent fabrication step where a second photoresist is patterned on the light-extraction film.

FIG. 6F is a cross-sectional view of the LED chip of FIG. 6E after a subsequent fabrication step where the second photoresist of FIG. 6E is removed.

FIG. 6G is a cross-sectional view of the LED chip of FIG. 6F after a subsequent fabrication step where the material of the islands of FIG. 6F is removed to form the internal cavities of the light-extraction elements.

FIG. 7 is a cross-sectional view of the LED chip of FIG. 2A with a superimposed and expanded top view of one of the light-extraction elements.

FIG. 8 is a top view of a portion of the light-extraction film for embodiments where the light-extraction elements form an array across the light-extraction film.

FIG. 9 is a top view of a portion of the light-extraction film that is similar to FIG. 8 for embodiments where the light-extraction elements are formed with an alternative shape.

FIG. 10 is a top view of a portion of the light-extraction film that is similar to FIG. 8 for embodiments where the light-extraction elements are formed with a yet another alternative shape.

FIG. 11 is an expanded top view of a portion of the light-extraction film that is similar to FIG. 8 for embodiments where the light-extraction elements are formed with a yet another alternative shape.

FIG. 12 is a cross-sectional view of an exemplary LED package that includes the light-extraction film and light-extraction elements according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to light-directing structures in LED devices and related methods. Exemplary light-directing structures include light-extraction films having one or more light-extraction elements with internal cavities for shaping emissions. Light-extraction elements and corresponding internal cavities are shaped to direct light emissions off center to provide LED devices with wider angle emissions. Internal cavities may be at least partially embedded within light-extraction films. Internal cavities may be bounded by angled inner sidewalls. Angled shapes of the inner sidewalls and/or further angled shapes of outer sidewalls of light-extraction elements may effectively promote light to exit the LED chip at desired emission angles. Exemplary LED devices include LED chips and LED packages.

An LED chip typically comprises an active LED structure or region that may have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. In certain applications, UV LEDs may also be provided with one or more lumiphoric materials to provide LED packages with aggregate emissions having a broad spectrum and improved color quality for visible light applications. Near-IR and/or IR wavelengths for LED structures of the present disclosure may have wavelengths above 700 nm, such as in a range from 750 nm to 1100 nm, or more.

An LED chip may also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, spectral density, etc. In certain embodiments, lumiphoric materials having cyan or green peak wavelengths may be used. In certain embodiments, the LED chip and corresponding lumiphoric material may be configured to primarily emit converted light from the lumiphoric material so that aggregate emissions include little to no perceivable emissions that correspond to the LED chip itself.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

In certain embodiments, one or more lumiphoric materials may be provided as at least a portion of a wavelength conversion element or cover structure that is provided over an LED chip. Wavelength conversion elements or cover structures may include a support element and one or more lumiphoric materials that are provided by any suitable means, such as by coating a surface of the support element or by incorporating the lumiphoric materials within the support element. In certain embodiments, the support element may be composed of a transparent material, a semi-transparent material, or a light-transmissive material, such as sapphire, SiC, silicone, and/or glass (e.g., borosilicate and/or fused quartz). Wavelength conversion elements and cover structures of the present disclosure may be formed from a bulk material which is optionally patterned and then singulated. In certain embodiments, the patterning may be performed by an etching process (e.g., wet or dry etching), or by another process that otherwise alters a surface, such as with a laser or saw. In certain embodiments, wavelength conversion elements and cover structures may comprise a generally planar upper surface that corresponds to a light emission area of the LED package. Wavelength conversion elements and cover structures may be attached to one or more LED chips using, for example, a layer of transparent adhesive. In various embodiments, wavelength conversion elements may comprise configurations such as phosphor-in-glass or ceramic phosphor plate arrangements. Phosphor-in-glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements.

The present disclosure can be useful for LED chips having a variety of geometries, such as vertical and/or flip-chip geometries. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described herein are applicable to flip-chip structures where anode and cathode connections are made from a same side of the LED chip for flip-chip mounting to another surface. In certain flip-chip embodiments, the growth substrate of the LED chip may form the intended light-exiting surface for the LED chip.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

Conventional LED chips are structured with light emission patterns with highest intensities centered in directions normal to top surfaces of the LED chips. In various lighting applications, it may be preferable to have different light emission patterns, such emission patterns where highest intensity emissions are directed off center. For example, certain applications may prefer light emissions with highest intensities that are provided at wider viewing angles. In conventional applications, LED devices employ LED package lenses and/or secondary optics with shapes that redirect light off center.

According to aspects of the present disclosure, various LED chips and LED packages are described with improved light-directing structures, such as light-extraction films having one or more light-extraction elements with internal cavities for shaping emissions. In certain aspects, light-extraction films are integrated within an LED chip. Light-extraction elements may include arrays of light-extraction elements with internal cavities. Each internal cavity may form a nested structure within a larger light-extraction element. Light generated within LED chips may bounce within internal cavities before achieving sufficient angles to enter angled inner sidewalls of the light-extraction element. Angled shapes of the inner sidewalls and/or further angled shapes of outer sidewalls of the light-extraction element may effectively promote light to exit the LED chip at desired emission angles. In further aspects, such light-extraction films may also be incorporated at an LED package level, such as a film provided on a chip cover. In such embodiments, the light-extraction films may provide desired emission angles while permitting the LED packages to have lower profiles than conventional LED packages with larger shaped optics and/or secondary optics.

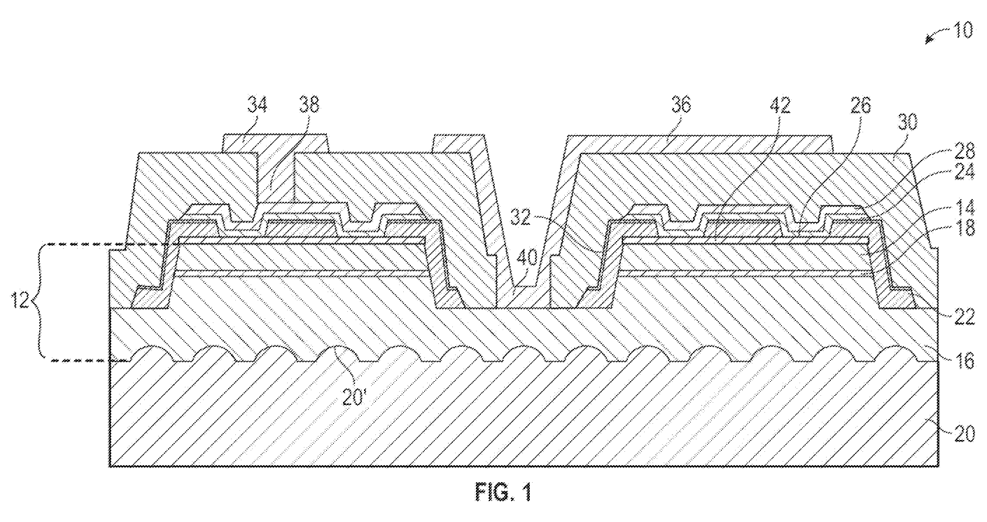

FIG. 1 is a cross-sectional view of an exemplary LED chip 10 according to principles of the present disclosure. FIG. 1 is provided in the context of a flip-chip structure that is applicable for use with light extraction films having light-extraction elements as described herein. While flip-chip structures are described for exemplary purposes, principles of the present disclosure are also applicable to other chip structures, such as vertical structures with anodes and cathodes on opposing sides, and/or structures where growth substrates are removed and mechanical support is provided by carrier submounts.

In FIG. 1, the LED chip 10 includes an active LED structure 12 comprising a p-type layer 14, an n-type layer 16, and an active layer 18 therebetween. The active LED structure 12 may be formed on a substrate 20. In certain embodiments, one or more buffer layers and/or undoped layers may be provided between the substrate 20 and n-type layer 16 of the active LED structure 12. In certain embodiments, the n-type layer 16 is between the active layer 18 and the substrate 20. In other embodiments, the doping order may be reversed. The substrate 20 can comprise many different materials such as SiC or sapphire and can have one or more surfaces that are shaped, textured, or patterned to enhance light extraction. In certain embodiments, the substrate 20 is light transmissive (preferably transparent) and may include a patterned surface 20’ that is proximate the active LED structure 12 and includes multiple recessed and/or raised features.

In FIG. 1, a dielectric reflective layer 22 is provided on portions of the p-type layer 14. The dielectric reflective layer 22 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the dielectric reflective layer 22 comprises a material with an index of refraction lower than the index of refraction of the active LED structure material. The dielectric reflective layer 22 may comprise many different materials, with some having an index of refraction less than 2.3, while others can have an index of refraction less than 2.15, less than 2.0, and less than 1.5. In certain embodiments, the dielectric reflective layer 22 comprises silicon dioxide (SiO₂) and/or silicon nitride (SiN). It is understood that many dielectric materials can be used such as SiN, SiNx, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof.

In certain embodiments, the dielectric reflective layer 22 may include multiple alternating layers of different dielectric materials, e.g., alternating layers of SiO₂ and SiN that symmetrically repeat or are asymmetrically arranged. Some Group III nitride materials such as GaN can have an index of refraction of approximately 2.4, SiO₂ can have an index of refraction of approximately 1.48, and SiN can have an index of refraction of approximately 1.9. Embodiments with the active LED structure 12 comprising GaN and the dielectric reflective layer 22 comprising SiO₂ may have a sufficient index of refraction step between the two to allow for efficient TIR of light. The dielectric reflective layer 22 may have different thicknesses depending on the type of materials used, with some embodiments having a thickness of at least 0.2 microns (μm). In some of these embodiments, the dielectric reflective layer 22 can have a thickness in the range of 0.2 μm to 0.7 μm, while in some of these embodiments the thickness can be approximately 0.5 μm. Portions of the dielectric reflective layer 22 may extend along mesa sidewalls of the active LED structure 12 and along sidewall portions of the p-type layer 14, the active layer 18, and the n-type layer 16.

The LED chip 10 may further include a reflective structure 24 that is on the dielectric reflective layer 22 such that the dielectric reflective layer 22 is arranged between the active LED structure 12 and the reflective structure 24. As described below in greater detail, the reflective structure 24 may embody a multiple layer metal reflective structure configured to reflect any light from the active LED structure 12 that may pass through the dielectric reflective layer 22. The reflective structure 24 can comprise many different materials such as Ag or alloys thereof, gold (Au) or alloys thereof, or combinations thereof. As illustrated, the reflective structure 24 may include one or more reflective layer interconnects 26 that provide electrically conductive paths through the dielectric reflective layer 22 to the p-type layer 14. In certain embodiments, the reflective layer interconnects 26 comprise reflective layer vias. In some embodiments, the reflective layer interconnects 26 comprise the same material as the reflective structure 24 and are formed at the same time as the reflective structure 24. In other embodiments, the reflective layer interconnects 26 may comprise a different material than the reflective structure 24.

The LED chip 10 may also comprise a barrier layer 28 on a side of the reflective structure 24 opposite the dielectric reflective layer 22 to prevent migration of the reflective structure material, such as Ag, to other layers. Preventing this migration helps the LED chip 10 maintain efficient operation throughout its lifetime. The barrier layer 28 may comprise an electrically conductive material, with suitable materials including but not limited to sputtered Ti/Pt followed by evaporated Au bulk material or sputtered Ti/Ni followed by an evaporated Ti/Au bulk material.

A passivation layer 30 may be included on the barrier layer 28 as well as any portions of the reflective structure 24 that may be uncovered by the barrier layer 28. The passivation layer 30 may further be arranged on portions of the dielectric reflective layer 22 that are uncovered by the reflective structure 24. The passivation layer 30 protects and provides electrical insulation for the LED chip 10 and can comprise many different materials, such as a dielectric material. In certain embodiments, the passivation layer 30 is a single layer, and in other embodiments, the passivation layer 30 comprises a plurality of layers. A suitable material for the passivation layer 30 includes but is not limited to SiN, SiNx, and/or Si₃N₄. In certain embodiments, the dielectric reflective layer 22 comprises SiO₂ and the passivation layer 30 comprises SiN, SiNx, or Si₃N₄. In other embodiments, the dielectric reflective layer 22 and at least a portion of the passivation layer 30 may each comprise SiO₂. As illustrated, the dielectric reflective layer 22 may bound perimeter and/or sidewall portions of the active LED structure 12, including the p-type layer 14, the active layer 18, and the n-type layer 16, along a perimeter of the LED chip 10. Furthermore, the passivation layer 30 may be arranged to also bound perimeter portions of the active LED structure 12. In this manner, portions of the dielectric reflective layer 22 may be arranged between portions of the passivation layer 30 along sidewalls of active LED structure 12 for enhanced passivation and protection.

Certain embodiments may also comprise one or more adhesion layers 32 positioned at one or more interfaces between the dielectric reflective layer 22 and the reflective structure 24 to promote improved adhesion therebetween. Many different materials can be used for the adhesion layer 32, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlₓO_{y}) or combinations thereof, with a preferred material being TiON, AlO, or AlxOy. In certain embodiments, the adhesion layer 32 comprises AlₓO_{y}, where 1≤x≤4 and 1≤y≤6. In certain embodiments, the adhesion layer 32 comprises AlₓO_{y}, where x=2 and y=3, or Al₂O₃. The adhesion layer 32 may be deposited by electron beam deposition that may provide a smooth, dense, and continuous layer without notable variations in surface morphology. The adhesion layer 32 may also be deposited by sputtering, chemical vapor deposition, plasma enhanced chemical vapor deposition, or atomic layer deposition (ALD).

In FIG. 1, the LED chip 10 comprises a p-contact 34 and an n-contact 36 that are arranged on the passivation layer 30 and are configured to provide electrical connections with the active LED structure 12. The p-contact 34, which may also be referred to as an anode contact, may comprise one or more p-contact interconnects 38 that extend through the passivation layer 30 to the barrier layer 28 or the reflective structure 24 to provide an electrical path to the p-type layer 14. In certain embodiments, the one or more p-contact interconnects 38 comprise one or more p-contact vias. The n-contact 36, which may also be referred to as a cathode contact, is electrically coupled to the n-type layer 16 by way of one or more n-contact interconnects 40 that extend through the passivation layer 30, the barrier layer 28, the dielectric reflector layer 22, the reflective structure 24, the p-type layer 14, and the active layer 18. In certain embodiments, the one or more n-contact interconnects 40 may be referred to as one or more n-contact vias. Openings for the n-contact interconnects 40 may be formed in a separate etching step than etching along the perimeter of the LED chip 10 where the passivation layer 30 bounds the active LED structure 12. For illustrative purposes, FIG. 1 is shown with a single n-contact interconnect 40. In practice, the LED chip 10 may include multiple n-contact interconnects 40 spaced apart in an array pattern across the active LED structure 12.

In operation, a signal applied across the p-contact 34 and the n-contact 36 is conducted to the p-type layer 14 and the n-type layer 16, causing the LED chip 10 to emit light from the active layer 18. The p-contact 34 and the n-contact 36 can comprise many different materials such as Au, copper (Cu), nickel (Ni), In, Al, Ag, tin (Sn), Pt, or combinations thereof. In still other embodiments, the p-contact 34 and the n-contact 36 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. In certain embodiments, the LED chip 10 is arranged for flip-chip mounting and the p-contact 34 and n-contact 36 are configured to be mounted or bonded to a surface, such as a printed circuit board. In this manner, the substrate 20 of the LED chip 10 forms a primary light emitting surface.

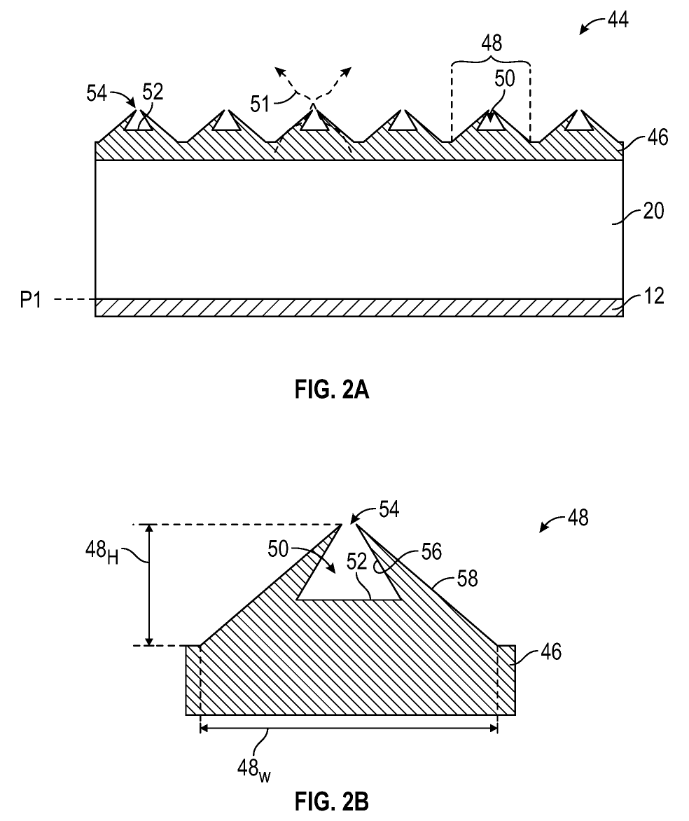

FIG. 2A is a generalized cross-sectional view of an LED chip 44 that is similar to the LED chip 10 of FIG. 1 for embodiments that include a light-extraction film 46. FIG. 2B is an expanded cross-sectional view of one of the light-extraction elements 48 of FIG. 2A. In FIG. 2A, the LED chip 44 is positioned in a flip-chip arrangement such that the active LED structure 12 is positioned below the substrate 20. With internal reflective layers, such as the reflective structure 24 and/or the dielectric reflective layer 22 of FIG. 1, light generated by the active LED structure 12 is directed to pass through the substrate 20 and exit the LED chip 44. The light-extraction film 46 is provided on the active LED structure 12 and in a path of light exiting the LED chip 44. In certain embodiments, the light-extraction film 46 is positioned on the substrate 20 such that the substrate 20 is between the active LED structure 12 and the light-extraction film 46. The light-extraction film 46 may comprise various materials that are light-transparent and/or light-transmissive to light generated by the active LED structure 12. For example, the light-extraction film 46 may comprise various dielectric oxides and/or nitrides, such as SiO₂, SiOx, TiO₂, Ta₂O₅, ITO, MgOx, ZnO, SiN, SiNx, Si₃N₄, Si, Ge, and/or combinations thereof. In still further embodiments, the light-extraction film 46 may form a stack of dielectric layers with variable thicknesses and/or indexes of refraction to provide a filter structure, such as a low pass, high pass, and/or band pass filter for light exiting the LED chip 44.

As illustrated in FIG. 2A, the light-extraction film 46 includes one or more light-extraction elements 48. By way of example, six light-extraction elements 48 are illustrated. In practice, light-extraction elements 48 may be formed with small enough dimensions that permit many more light-extraction elements 48 that form an array across the LED chip 44. Each light-extraction element 48 may include an internal cavity 50 that provides the remainder of the light-extraction element 48 with a shape that directs light 51 in directions that are off center or angled relative to a direction perpendicular to a longitudinal plane P1 of the active LED structure 12. As illustrated, light 51 that enters portions of the light-extraction film 46 that define boundaries of each internal cavity 50 may reflect and/or refract along these portions and exit the LED chip 44 with wider angled emissions. In certain aspects, light that enters the internal cavities 50 may also be subject to reflection and/or refraction until achieving a sufficient incident angle to pass into the light-extraction element 48.

A base 52 of the internal cavity 50 is positioned within the light-extraction film 46 and closer to the active LED structure 12 than other portions of the internal cavity 50, such as a top 54 of the internal cavity 50. In certain embodiments, the top 54 of the internal cavity 50 is open at a surface of the light-extraction film 46, thereby defining an opening to the remainder of the underlying internal cavity 50. In certain embodiments, the base 52 is wider than the top 54 of the internal cavity 50, thereby defining inner sidewalls 56 of the light-extraction element 48 formed at an off angle relative to a direction perpendicular to the longitudinal plane P1 of the active LED structure 12. The light-extraction element 48 is bounded by outer sidewalls 58 of the light-extraction element 48 that are also formed at an off angle relative to a direction perpendicular to the longitudinal plane P1 of the active LED structure 12. In certain embodiments, the angle of the inner sidewalls 56 is less than the angle of the outer sidewalls 58. By way of example, the angle of the inner sidewalls 56 may be formed in a range from 15 to 45 degrees relative to the perpendicular direction from the longitudinal plane P1 and the angle of the outer sidewalls 58 may be formed in a range from 30 to 60 degrees relative to the perpendicular direction from the longitudinal plane P1. As illustrated, the shape of each light-extraction element 48 defined between the inner sidewalls 56 and the outer sidewalls 58 may form cross-sectional profile of a wing or antenna structure that is angled toward the top 54 for directing light in a desired direction. In various applications, the overall shape of each light-extraction element 48 may form one or more of a cone, a tetrahedron, a polygonal pyramid structure, a pyramid with a square base, a pyramid with a hexagonal base, a triangular prism, an irregular polygon, and a star polygon, among others.

While not necessarily drawn to scale, a height 48_{H} of the light-extraction element 48 may be less than a width 48_{W} of the light-extraction element 48. In certain embodiments, a ratio of the height 48_{H} to the width 48_{W} of the light-extraction element 48 may be about 1:1. In still further embodiments, the height 48_{H} may be greater than the width 48_{W}, for example a ratio of the height 48_{H} to the width 48_{W} of the light-extraction element 48 may be in a range from 1:1 up to 3:1.

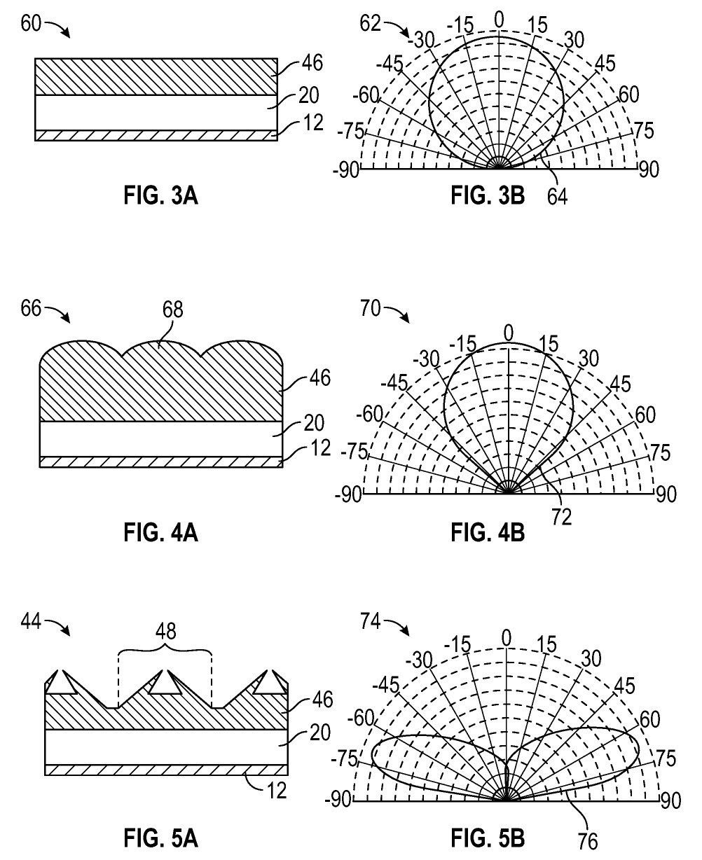

FIGS. 3A to 5B illustrate various examples of LED chips with and without light extraction elements and corresponding emission patterns according to principles of the present disclosure. The emission pattern plots of FIGS. 3B, 4B, and 5B represent far field emission patterns for each of the LED chips represented in FIGS. 3A, 4A, and 5A. The far field emission patterns illustrate emission intensity relative to emission angle, where an angle of 0 degrees represents a perpendicular direction to the longitudinal plane P1 of FIG. 2A.

FIG. 3A is a general cross-sectional view of an LED chip 60 where a top surface of the LED chip 60 is generally planar. As illustrated, the light-extraction film 46 is formed with a generally planar top surface. In this manner, an emission pattern of the LED chip 60 may generally be expected to be similar to embodiments where the light-extraction film 46 is omitted and the top surface of the substrate 20 forms a planar light emitting surface. FIG. 3B is plot 62 of a far field emission pattern 64 of the LED chip 60 of FIG. 3A. As illustrated, the planar top surface of the LED chip 60 provides a generally Lambertian profile for the far field emission pattern where peak intensity is at or near perpendicular (i.e., 0 degrees in FIG. 3B).

FIG. 4A is a general cross-sectional view of an LED chip 66 where a top surface of the LED chip 66 is formed with a nonplanar shape. For example, a top of the light-extraction film 46 is formed with an array of curved features 68, such as domes that may enhance light extraction. With the curved features 68 illustrated as integral to the light-extraction film 46, the associated emission pattern of FIG. 4B would generally be expected to be similar to embodiments where the light-extraction film 46 is omitted and the top surface of the substrate 20 forms the curved features 68. FIG. 4B is plot 70 of a far field emission pattern 72 of the LED chip 66 of FIG. 4A. As illustrated, the curved features 68 of the LED chip 66 may still provide peak intensity at or near perpendicular (i.e., 0 degrees in FIG. 4B).

FIG. 5A is a general cross-sectional view of a portion of the LED chip 44 of FIG. 2A according to principles of the present disclosure. As illustrated, the light-extraction film 46 includes at least one light-extraction element 48 as described for FIGS. 2A and 2B. FIG. 5B is plot 74 of a far field emission pattern 76 of the LED chip 44 of FIG. 5A. As illustrated, the far field emission pattern 76 exhibits wing shapes extending away from perpendicular. In this regard, peak intensities are angled off center, such as between 60 and 75 degrees for positive and/or negative angles relative to perpendicular. Accordingly, light-extraction films 46 with light-extraction elements 48 as described herein may advantageously provide off angle emission patterns in LED chips and/or LED devices without added complexity and costs associated with additional lenses or secondary optics.

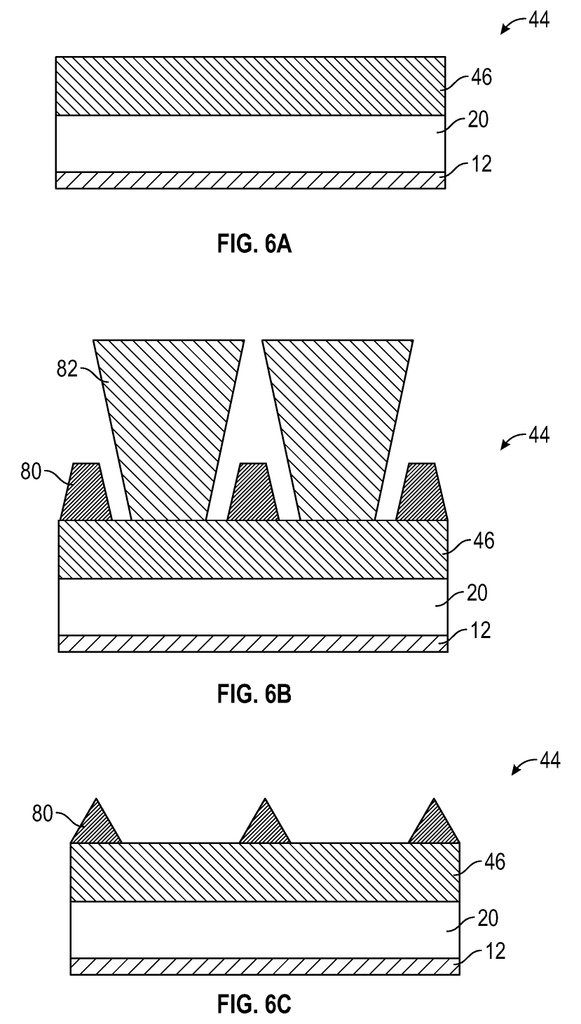

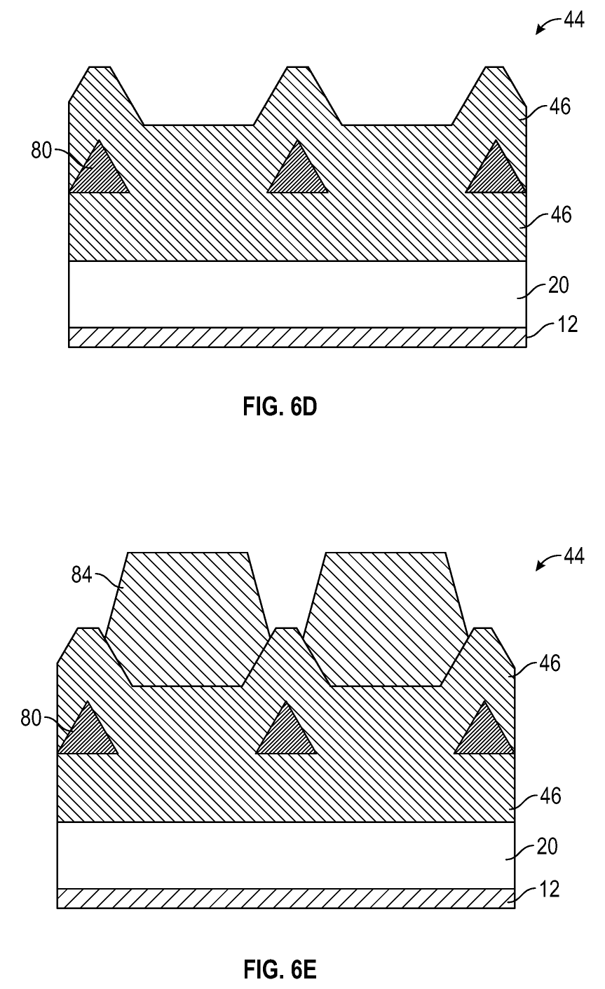

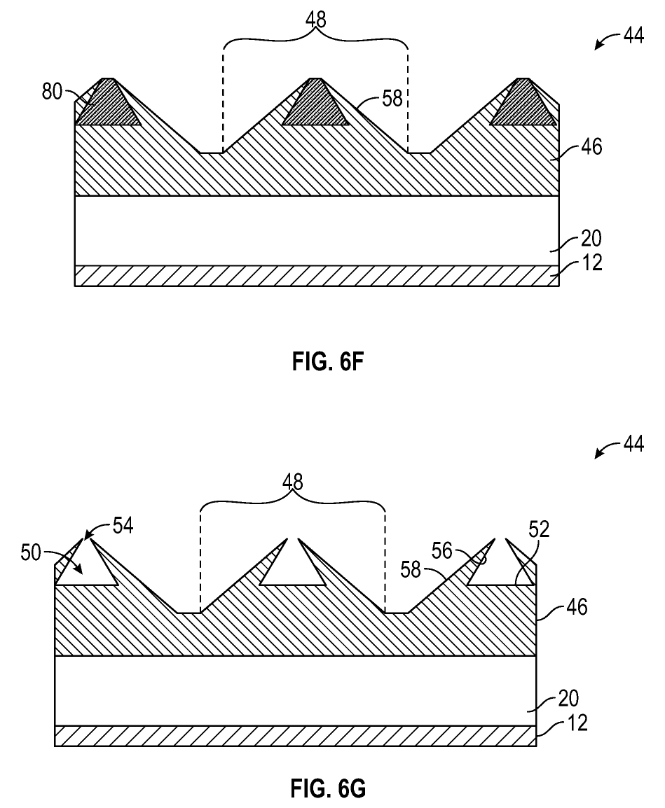

FIGS. 6A to 6G are cross-sectional views of a portion of the LED chip 44 of FIG. 2A illustrating various fabrication steps for forming light-extraction films 46 with light-extraction elements 48. For illustrative purposes, FIGS. 6A to 6G are provided from the perspective of a single LED chip 44. In practice, the fabrication steps of FIGS. 6A to 6G may be performed at the wafer level and large numbers of the LED chips 44 may subsequently be singulated.

FIG. 6A is a cross-sectional view of the LED chip 44 of FIG. 2A after a fabrication step for forming a portion of the light-extraction film 46. The light-extraction film 46 may be deposited on a surface of the substrate 20 and/or the active LED structure 12. In FIG. 6A, a portion of the light-extraction film 46 is first deposited and remaining portions of the light-extraction film 46 will later be deposited as later described for FIG. 6D.

FIG. 6B is a cross-sectional view of the LED chip 44 of FIG. 6A after a subsequent fabrication step where a number of islands 80 or dots are formed on the light-extraction film 46. The islands 80 of material may be selectively deposited by way of a first photoresist 82 that is patterned on the light-extraction film 46. By way of example, the material of the islands 80 may comprise Al, Au, Cu or other metals. In certain embodiments, the islands 80 may be deposited in various patterns, such as a hexagonal close packed pattern. As will be later described below for FIGS. 6C to 6G, the islands 80 may define locations for the internal cavities 50 of FIG. 2A.

FIG. 6C is a cross-sectional view of the LED chip 44 of FIG. 6B after a subsequent fabrication step where the first photoresist 82 of FIG. 6B is removed and the islands 80 are etched to form a shape. By way of example, the islands 80 of FIG. 6C are etched to have a cross-sectional shape of a triangle, which may correspond with a three-dimensional shape of a cone in certain embodiments. In addition to the shape of a cone, the islands 80 may have various other shapes, such as a tetrahedron, a polygonal pyramid structure, a pyramid with a square base, a pyramid with a hexagonal base, a triangular prism, an irregular polygon, and a star polygon, among others.

FIG. 6D is a cross-sectional view of the LED chip 44 of FIG. 6C after a subsequent fabrication step where a remaining portion of the light-extraction film 46 is deposited on the islands 80 and on the previously formed portion of the light-extraction film 46. As illustrated, the light-extraction film 46 may be formed to conformally cover the islands 80.

FIG. 6E is a cross-sectional view of the LED chip 44 of FIG. 6D after a subsequent fabrication step where a second photoresist 84 is patterned on the light-extraction film 46. As illustrated, the second photoresist 84 may be formed with a positive or negative retrograde structure. As will be described below for FIG. 6F, the retrograde structure of the second photoresist 84 will be used to define the outer sidewalls 58 of the light-extraction element 48.

FIG. 6F is a cross-sectional view of the LED chip 44 of FIG. 6E after a subsequent fabrication step where the second photoresist 84 of FIG. 6E is removed. In certain embodiments, a dry etch is applied to remove the second photoresist 84 of FIG. 6E while also removing the portions of the light-extraction film 46 accessible through the pattern of the second photoresist 84 of FIG. 6E. As illustrated, the etching may remove portions of the light-extraction film 46 to expose top surfaces of the islands 80 at a top surface of the light-extraction film 46. Additionally, the etching may define the outer sidewalls 58 of the light-extraction element 48.

FIG. 6G is a cross-sectional view of the LED chip 44 of FIG. 6F after a subsequent fabrication step where the material of the islands 80 of FIG. 6F is removed to form the internal cavities 50 of the light-extraction elements 48. In certain embodiments, a wet etch may be applied to remove the islands 80 of FIG. 6F, leaving behind the shape of the internal cavities 50. As illustrated, the base 52 and inner sidewalls 56 of the light-extraction elements 48 are also defined by removing the islands 80 of FIG. 6F.

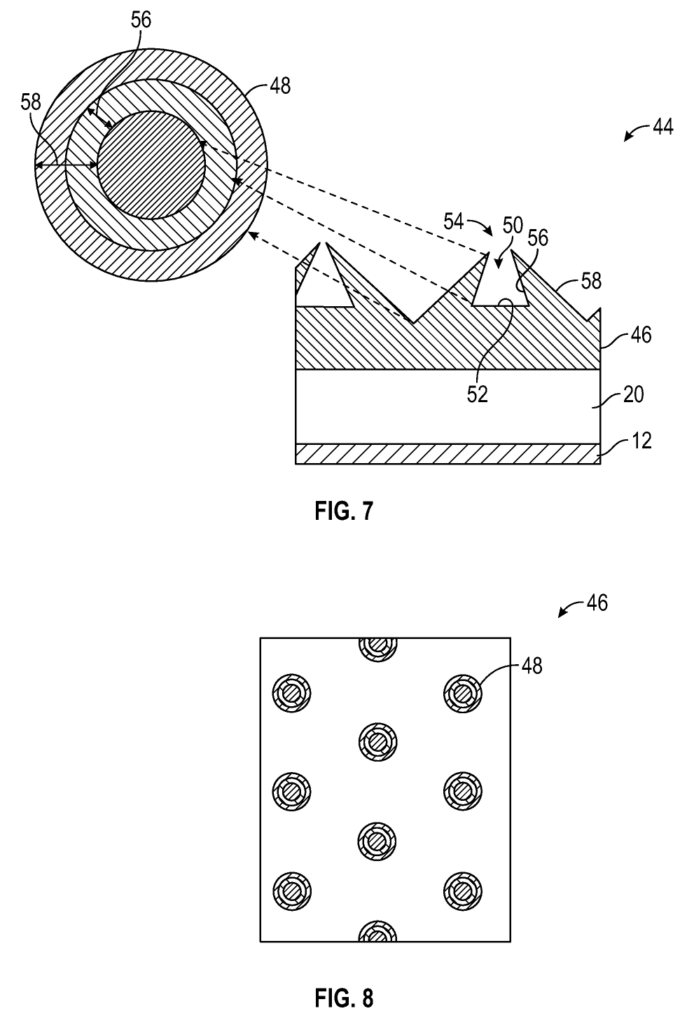

FIG. 7 is a cross-sectional view of the LED chip 44 of FIG. 2A with a superimposed and expanded top view of one of the light-extraction elements 48. For illustrative purposes, dashed line arrows are provided to indicate locations of various portions of the light-extraction element 48 between the cross-sectional view and the superimposed and expanded to view. In the example of FIG. 7, the light-extraction element 48 forms a cone shape with an opening in the light-extraction film 46 that corresponds with the top 54 of the internal cavity 50.

As described above, light-extraction elements 48 may be formed in arrays across light-extraction films 46 according to principles of the present disclosure. Such arrays may be formed in various patterns and light-extraction elements 48 may embody various shapes, such as one or more of a cone, a tetrahedron, a polygonal pyramid structure, a pyramid with a square base, a pyramid with a hexagonal base, a triangular prism, and a star polygon, among others. FIGS. 8 to 11 provide various exemplary patterns and shapes of the light-extraction elements 48.

FIG. 8 is a top view of a portion of the light-extraction film 46 for embodiments where the light-extraction elements 48 form an array across the light-extraction film 46. By way of example, the light-extraction elements 48 in FIG. 8 are formed with cone shapes with openings as described above for FIG. 7.

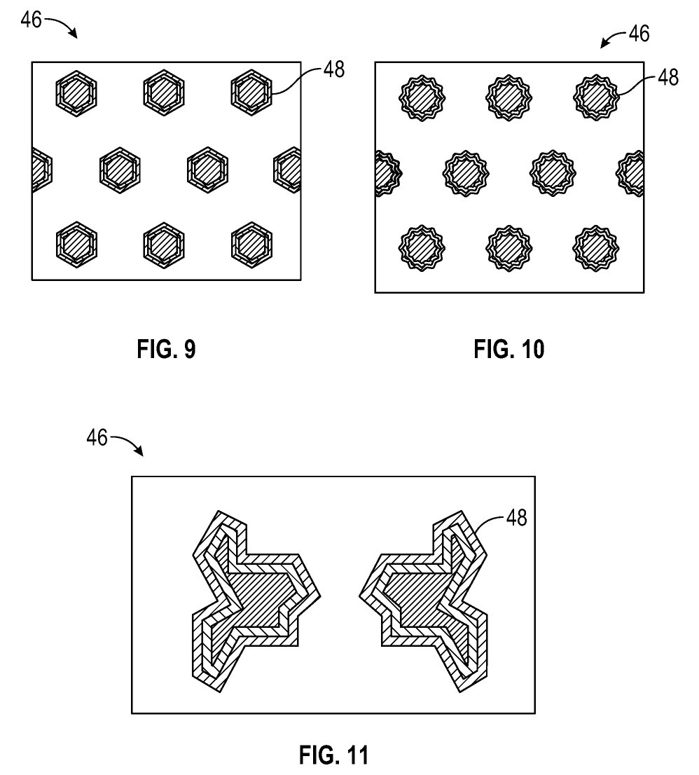

FIG. 9 is a top view of a portion of the light-extraction film 46 that is similar to FIG. 8 for embodiments where the light-extraction elements 48 are formed with an alternative shape. In FIG. 9, the light-extraction elements 48 are formed with a hexagonal outer shape. The remainder of the light-extraction elements 48 may be structured in a similar manner as described above for FIG. 7.

FIG. 10 is a top view of a portion of the light-extraction film 46 that is similar to FIG. 8 for embodiments where the light-extraction elements 48 are formed with a yet another alternative shape. In FIG. 10, the light-extraction elements 48 are formed with an outer shape of a star polygon. The remainder of the light-extraction elements 48 may be structured in a similar manner as described above for FIG. 7.

FIG. 11 is an expanded top view of a portion of the light-extraction film 46 that is similar to FIG. 8 for embodiments where the light-extraction elements 48 are formed with a yet another alternative shape. In FIG. 11, the light-extraction elements 48 are formed with an outer shape of an irregular polygon. The remainder of the light-extraction elements 48 may be structured in a similar manner as described above for FIG. 7.

While the previous embodiments are described in the context of LED chips, the light-extraction films described herein may also be incorporated at an LED package level, such as a film provided on a chip cover. In such embodiments, the light-extraction films may provide desired emission angles while permitting the LED packages to have lower profiles than conventional LED packages with larger shaped optics and/or secondary optics.

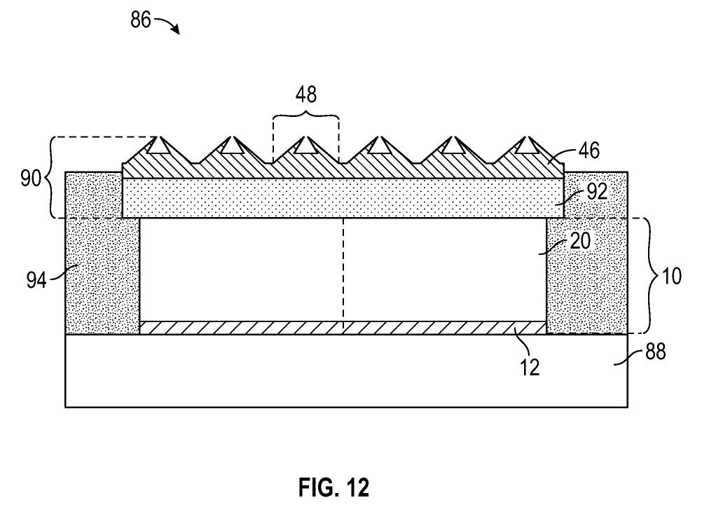

FIG. 12 is a cross-sectional view of an exemplary LED package 86 that includes the light-extraction film 46 and light-extraction elements 48 according to principles of the present disclosure. By way of example, the LED package 86 may include the LED chip 10 as described above for FIG. 1. A single LED chip or a plurality of LED chips may be provided as indicated by the vertical dashed line. The LED chip 10 is mounted to a support structure 88 of the LED package 86. The support structure 88 may embody a submount or a lead frame structure for the LED package 86. In certain embodiments, the light-extraction film 46 and light-extraction elements 48 may be integrated as part of a cover structure 90 of the LED package 86. The light-extraction film 46 and light-extraction elements 48 may be formed on a support element 92 of the cover structure 90 in a similar manner described above for FIGS. 6A to 6G by substituting the support element 92 for the substrate 20 and active LED structure 12 of FIGS. 6A to 6G. In certain embodiments, the support element 92 may be composed of a transparent material, a semi-transparent material, or a light-transmissive material, such as sapphire, SiC, silicone, and/or glass (e.g., borosilicate and/or fused quartz). In still further embodiments, a lumiphoric material may be incorporated within the support element 92 and/or as part of the cover structure 90.

As further illustrated in FIG. 12, a light-altering layer 94 may be provided on the support structure 88 and surrounding lateral edges of the LED chip 10 and portions of the cover structure 90. The light-altering layer 94 may include a light-reflective material and/or a light-refracting material that effectively redirects laterally propagating light back toward a desired emission direction, such as through the light-extraction film 46 and light-extraction elements 48. In certain embodiments, the light-altering layer 94 may also be positioned about lateral edges of support element 92 and/or the light-extraction film 46. In this manner, the cover structure 90 forms a primary emission surface of the LED package 86 and light exiting the LED package 86 may exhibit an emission profile similar to FIG. 5B. For light-reflecting embodiments, the light-altering layer 94 may have a predominantly white color. Alternatively, the light-altering layer 94 may be provided with a predominantly black color to provide increased contrast for light passing through the cover structure 90.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
an active LED structure comprising an n-type layer, a p-type layer, and an active layer between the n-type layer and the p-type layer; and
a light-extraction film on the active LED structure, the light extraction film comprising a light-extraction element that includes an internal cavity bounded by inner sidewalls of the light-extraction film.

2. The LED chip of claim 1, further comprising a substrate between the active LED structure and the light-extraction film.

3. The LED chip of claim 1, wherein a base of the internal cavity is positioned closer to the active LED structure than a top of the internal cavity, and the base of the internal cavity is wider than the top of the internal cavity.

4. The LED chip of claim 3, wherein the top of the internal cavity is open at a surface of the light-extraction film.

5. The LED chip of claim 3, wherein the internal cavity forms a shape of a cone within the light-extraction element.

6. The LED chip of claim 1, wherein the light-extraction element forms a shape of a polygonal pyramid structure.

7. The LED chip of claim 1, wherein the light-extraction element is one of a plurality of light-extraction elements, and each light-extraction element of the plurality of light-extraction elements includes a separate internal cavity bounded by angled sidewalls of the light-extraction film.

8. The LED chip of claim 1, wherein the inner sidewalls of the light-extraction element are formed at a first angle in a range from 15 to 45 degrees from a direction perpendicular to a longitudinal plane of the active LED structure.

9. The LED chip of claim 8, wherein the light-extraction element is bounded by outer sidewalls of the light-extraction element, and the outer sidewalls are formed at a second angle in a range from 30 to 60 degrees from the direction perpendicular to the longitudinal plane of the active LED structure.

10. The LED chip of claim 1, wherein a ratio of a height of the light-extraction element to a width of the light-extraction element is in a range from one-to-one up to three-to-one.

11. A method comprising:
providing an active light-emitting diode (LED) structure comprising an n-type layer, a p-type layer, and an active layer between the n-type layer and the p-type layer;
forming a light extraction film on the active LED structure; and
forming a light-extraction element in the light extraction film, the light-extraction element forming an internal cavity bounded by inner sidewalls of the light-extraction film.

12. The method of claim 11, wherein forming the light-extraction element comprises:
depositing a first portion of the light-extraction film;
forming an island of material on the first portion of the light extraction film;
depositing a remaining portion of the light-extraction film over the island of material; and
removing the island of material to form the internal cavity of the light-extraction element.

13. The method of claim 12, further comprising etching the island of material to form a first shape before depositing the remaining portion of the light-extraction film, wherein the first shape corresponds with a shape of the internal cavity.

14. The method of claim 13, further comprising exposing a top surface of the island of material at a top surface of the light-extraction film before removing the island of material.

15. The method of claim 11, wherein a base of the internal cavity is positioned closer to the active LED structure than a top of the internal cavity, and the base of the internal cavity is wider than the top of the internal cavity.

16. A light-emitting diode (LED) package, comprising:
an LED chip; and
a light-extraction film on the LED chip, the light extraction film comprising a plurality of light-extraction elements, each light-extraction element of the plurality of light-extraction elements forming an internal cavity bounded by inner sidewalls of the light-extraction film.

17. The LED package of claim 16, further comprising a cover structure on the LED chip, the cover structure comprising a support element, wherein the light-extraction film is on the support element.

18. The LED package of claim 16, further comprising a support structure on which the LED chip is mounted, the support structure comprising a submount or a lead frame structure.

19. The LED package of claim 16, wherein a base of the internal cavity is positioned closer to the LED chip than a top of the internal cavity, and the base of the internal cavity is wider than the top of the internal cavity.

20. The LED package of claim 16, wherein a ratio of a height of each light-extraction element of the plurality of light extraction elements to a width of each light-extraction element of the plurality of light extraction elements is in a range from one-to-one up to three-to-one.

21. The LED package of claim 16, wherein each light-extraction element is bounded by outer sidewalls, and wherein the inner sidewalls and the outer sidewalls are formed at angles offset from a direction perpendicular to a longitudinal plane of an active LED structure of the LED chip.
